(19) United States
(12) Patent Application Publication
(10) Pub. No.: US 2011/0062535 A1
(43) Pub. Date: Mar. 17, 2011

(54) MEMS TRANSDUCERS

(76) Inventors: Robert Errol McMullen, Edinburgh (GB); Richard Ian Laming, Edinburgh (GB); Anthony Bernard Traynor, Livingston (GB); Tsjerk Hans Hoekstra, Edinburgh (GB)

(21) Appl. No.: 12/991,378

(22) PCT Filed: May 7, 2009
(86) PCT No.: PCT/GB09/50473

§ 371 Date: Nov. 18, 2010

(30) Foreign Application Priority Data
May 7, 2008 (GB) 0808294.3
May 7, 2008 (GB) 0808298.4

(51) Int. Cl. H01L 29/84; H01L 21/302

(52) U.S. Cl. 257/419; 438/53; 257/E29.324; 257/E21.214

(57) ABSTRACT

A MEMS device comprises a substrate having at least a first transducer optimized for transmitting pressure waves, and at least a second transducer optimized for detecting pressure waves. The transducers can be optimised for transmitting or receiving by varying the diameter, thickness or mass of the membrane and/or electrode of each respective transducer. Various embodiments are described showing arrays of transducers, with different configurations of transmitting and receiving transducers. Embodiments are also disclosed having an array of transmitting transducers and an array of receiving transducers, wherein elements in the array of transmitting and/or receiving transducers are arranged to have different resonant frequencies. At least one of said first and second transducers may comprise an internal cavity that is sealed from the outside of the transducer.

The present invention relates to transducers, and in particular to microelectromechanical systems (MEMS) ultrasonic transducers.

### BACKGROUND

Volumetric ultrasound imaging, whereby a full set of data of all points in 3D space is acquired, is driven by next generation requirements to obtain and retrieve the complete information set in one operation and have it available for later review and analysis. These requirements are driven by various market segments, including military (sonar), industrial (non-destructive testing), automotive (collision avoidance) and medical (non-invasive imaging) markets.

In addition to the market drivers and need, there are clear technical issues fuelling developments. Real-time ultrasonic volumetric imaging has only now become a possibility due to increased digital processing power, which allows for real-time data analysis of a large number of parallel signals. However, this requires high-density 2D ultrasonic transducer arrays to provide sufficient spatial resolution in, for example, medical applications. Also, these high-density matrix configurations can allow electronic beam-steering to scan fast and accurately through a complete volume. To facilitate the huge amounts of data transfer to and from the 2D array, it is essential that pre and post data processing take place as close to the 2D array as possible. This is extremely difficult to achieve with current piezo crystal transducers.

There are also applications for lower-density concentrations of ultrasound transducers. For example, one area of development is that of gesture recognition in devices employing just a few transducers. Such transducers may transmit ultrasound waves and detect the reflected waves from a nearby user. The detected reflected waves may be processed to determine a gesture performed by, for example, the hand of the user, which is thereby used to control the device itself. This may comprise an application where the transducer is encapsulated.

Semiconductor technology is ideally suited to meet the requirements for volumetric imaging, as semiconductor fabrication techniques allow for relatively large array sizes in optimised configurations and also allow for the monolithic integration of the transducers with the processing electronics relatively close to the array. This is in contrast to the piezo crystal technology which is currently used for manufacturing of ultrasound probes. These are mechanically machined from bulk material in a sequential manufacturing process and require wire bonding of all individual pixels. Further, the frequency response of these piezo elements is not optimal for high frequency, mixed frequency and high bandwidth operation, which limits their use for some emerging advanced applications of ultrasound arrays.

Microelectromechanical systems (MEMS) ultrasound transducers are a new approach to ultrasound sensors. They are constructed using silicon micromachining technology which enables a plurality of small membranes in the order of microns in size suspended above submicron gaps to be constructed with greater accuracy than ever before.

There has been much interest and activity in this area from the academic and business communities, and consequently a number of manufacturing processes have been developed to produce MEMS ultrasonic transducers. The predominant method is the sacrificial release process. Although many variations of this process have been published they are all based an the same principle: a cavity or air-space is created below a suspended flexible membrane by growing/depositing a sacrificial layer and depositing the membrane over the sacrificial layer; the sacrificial layer is then removed, freeing the membrane and allowing it to move.

FIG. 1 shows this known manufacturing process.

FIG. 1a shows a substrate 10, and an insulating layer 12 above the substrate 10. In the first step of the process, an electrode 14 is deposited on the insulating layer 12.

A portion 16 of sacrificial material is then deposited over the electrode (FIG. 1b). An example of a suitable sacrificial material is polyimide. One method of depositing the sacrificial portion 16 in the required shape and location is to first deposit a layer of sacrificial material over the insulating layer 12. The sacrificial layer is then cured at an elevated temperature, and patterned with photoresist. The final sacrificial portion 16 is achieved by etching with an anisotropic oxygen plasma.

A membrane layer 18 is then deposited over the insulating material 12 and the sacrificial portion 16 (FIG. 1c). A suitable material for the membrane is silicon nitride. A second electrode 20 is deposited on the membrane layer 18 above the sacrificial portion 16 (FIG. 1d). Release holes 22 are etched through the second electrode 20 and the membrane layer 18, (FIG. 1e). Finally, the sacrificial portion 16 is etched away in a wet-etch process, for example, the release holes 22 allowing etchant to access the sacrificial material beneath, and the etched material to flow out of the transducer. The membrane is therefore free to move relative to the substrate (FIG. 1f).

In operation, the transducer may be used to generate pressure waves (e.g. acoustic or ultrasonic signals) by applying a potential difference between the two electrodes 14, 20. The potential difference causes the membrane to displace, and thus a modulated potential difference can be used to generate waves of variable frequency.

Alternatively, the transducer can also be used to detect such pressure waves. An incoming wave will cause the membrane to displace, and the variation in capacitance this causes between the two electrodes 14, 20 can be measured to determine the frequency and amplitude of the incoming wave.

A paper by Ergun et al entitled (“Capacitive Micromachined Ultrasonic Transducers: Fabrication Technology”, IEEE Trans. Ultra. Ferro. Freq. Control, pp 2242-58, December 2005) describes the fabrication of a 2D array of ultrasonic transducers. However, a goal of this research is to produce an array of transducers which are as uniform as possible in shape, dimensions, etc.

### SUMMARY OF INVENTION

According to a first aspect of the present invention, there is provided a microelectromechanical systems (MEMS) device, comprising: a substrate; and a plurality of transducers positioned on the substrate, said plurality of transducers comprising: at least a first transducer adapted to transmit pressure waves; and at least a second transducer adapted to detect pressure waves.

In one embodiment at least one of said first and second transducers comprises a cavity, said cavity being sealed from the outside of the transducer.

According to a second aspect of the present invention, there is provided a method of manufacturing a microelectromechanical systems (MEMS) device, said MEMS device comprising a substrate, said substrate having at least a first site for a first transducer adapted to transmit pressure waves and at least a second site for a second transducer adapted to detect pressure waves, said method comprising: forming said first transducer on said first site, and said second transducer on said second site.

According to a further aspect of the invention, there is provided a microelectromechanical systems (MEMS) device, comprising: a substrate; and a plurality of transducers positioned on the substrate, said plurality of transducers comprising: at least a first transducer adapted to transmit or detect pressure waves having a first frequency; and at least a second transducer adapted to transmit or detect pressure waves having a second frequency, wherein said first frequency is different from said second frequency.

In one embodiment at least one of said first and second transducers comprises a cavity, said cavity being sealed from the outside of the transducer.

According to a further aspect of the invention, there is provided a method of manufacturing a microelectromechanical systems (MEMS) device, said MEMS device comprising a substrate, said substrate having at least a first site for a first transducer adapted to transmit or detect pressure waves having a first frequency and at least a second site for a second transducer adapted to transmit or detect pressure waves having a second frequency, said first frequency being different from said second frequency, said method comprising: forming said first transducer on said first site, and said second transducer on said second site.

According to a further aspect of the present invention, there is provided a method of manufacturing a microelectromechanical systems (MEMS) device, said MEMS device comprising a substrate, said substrate having at least a first site for a first transducer adapted to transmit or detect pressure waves, said method comprising: depositing a first portion of sacrificial material on said first site, depositing a first membrane layer over at least the first site, forming a release channel prior to the step of depositing the first portion of sacrificial material; etching away the first portion of sacrificial material via the release channel; and sealing the release channel.

### BRIEF DESCRIPTION OF THE DRAWINGS

For a better understanding of the present invention, and to show more clearly how it may be carried into effect, reference will now be made, by way of example, to the following drawings, in which:

FIGS. 1a to 1f show a known process of manufacturing a MEMS transducer;

FIG. 2 is a graph comparing the frequency response of a membrane with a relatively high Q factor and a membrane with a relatively low Q factor;

FIG. 3 is a graph modelling the variation of the first resonant frequency of a transducer with membrane thickness;

FIG. 4 shows a 2D array according to the present invention;

FIGS. 5a and 5b both show a transducer adapted to transmit pressure waves and a transducer adapted to detect pressure waves according to aspects of the present invention;

FIGS. 6a and 6b both show a transducer adapted to transmit pressure waves and a transducer adapted to detect pressure waves according to other aspects of the present invention;

FIGS. 7a and 7b both show a transducer adapted to transmit pressure waves and a transducer adapted to detect pressure waves according to further aspects of the present invention;

FIGS. 8a to 8k show a process for manufacturing a MEMS device according to the present invention; and

FIGS. 9a-9p show alternative processes for manufacturing a MEMS device according to the present invention.

### DETAILED DESCRIPTION

The inventors of the present invention found that it is possible to adapt MEMS transducers specifically to either transmit, or detect, pressure waves. In particular, it was found that, by varying various dimensions and parameters associated with the transducer, the Q factor of the transducer could be changed. A transducer with a relatively high Q factor is better suited to transmitting pressure waves, as it has a high response over a relatively narrow range of frequencies (i.e. it transmits pressure waves having a relatively well-defined frequency and high amplitude). Conversely, a transducer with a relatively low Q factor is better suited to detecting pressure waves, as it has a less strong, but more consistent, response over a relatively broad range of frequencies (i.e. it can detect incoming pressure waves which may have a broader range of frequencies).

Some of the various embodiments of the invention described below relate to a MEMS device that is sealed or closed from environmental parameters. By sealed it is meant that the transducer comprises at least one internal cavity that is closed from the outside.

It is noted that the sealed aspect of the invention is described in relation to embodiments comprising a plurality of transducers. However, it is noted that the sealed aspect of the invention also applies to just a single transducer.

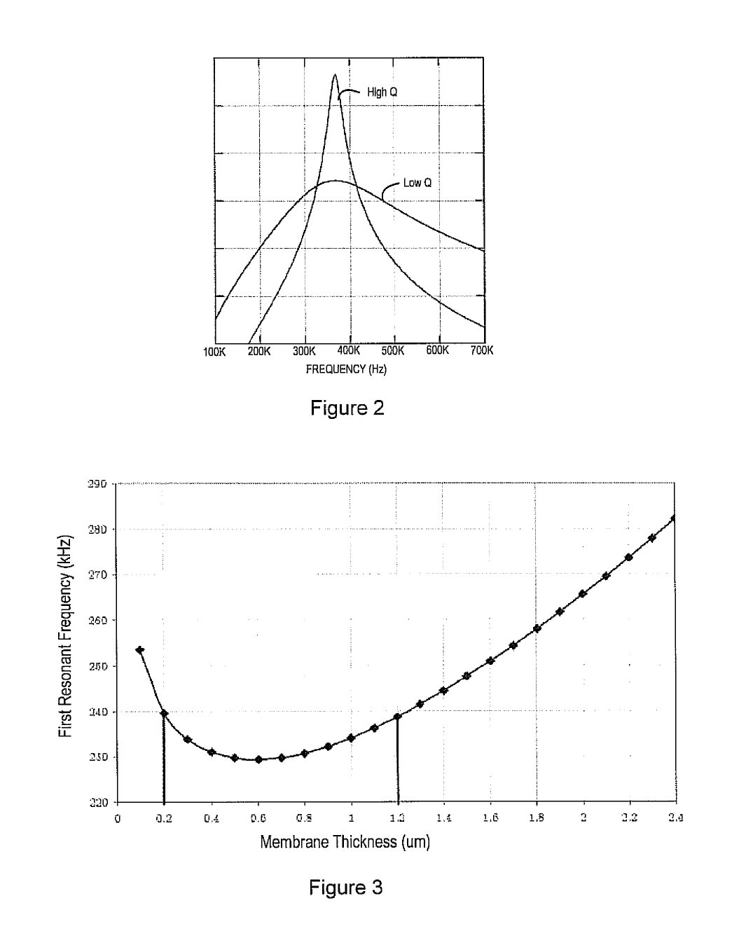

FIG. 2 is a graph comparing the frequency response of a membrane with a relatively high Q factor and a membrane with a relatively low Q factor. As can be seen, the membrane with the relatively high Q factor has a high response over a narrow range of frequencies, in the illustrated example, around a central frequency of approximately 370 kHz; the response of this membrane at frequencies away from the central frequency is comparatively low. The membrane with the relatively low Q factor has the same central frequency of 370 kHz; the membrane's response at this central frequency is lower, but at frequencies away from the central frequency, the response is higher than the membrane with the high Q factor. That is, the response of the membrane with the low Q factor is relatively more consistent than that of the membrane with the high Q factor over a larger range of frequencies.

In FIG. 2, the two membranes have the same central, i.e. resonant, frequency. This can be achieved by appropriately adjusting parameters and dimensions of the transducer as described in more detail below. Further, however, there are advantages in forming transducers with differing resonant frequencies, and this will also be described in greater detail below.

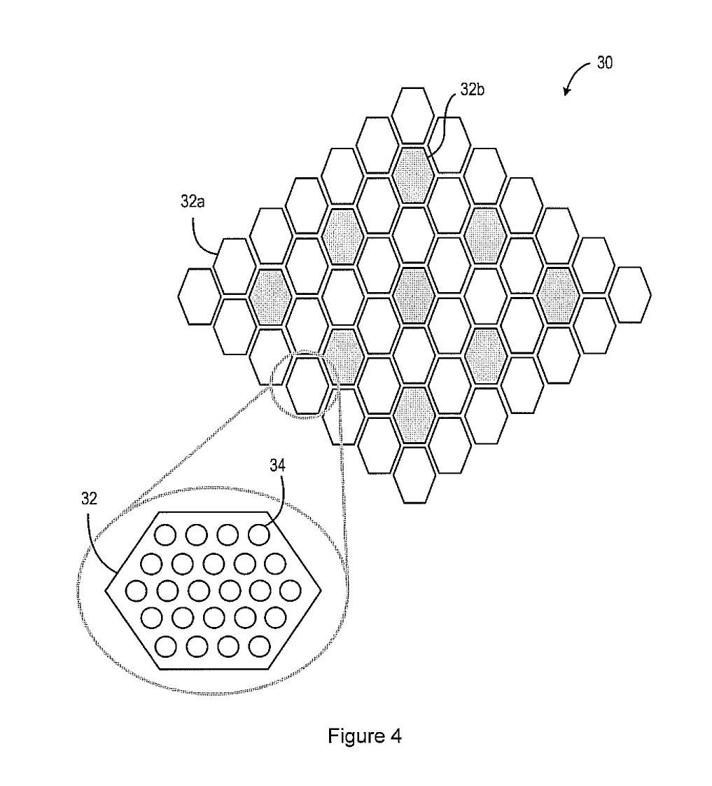

One dimension that affects the performance of the transducer is the thickness of the membrane. FIG. 3 is a graph modelling the variation of the first resonant frequency of a transducer with membrane thickness when all other dimensions and parameters are kept constant. In the illustrated example, the membrane diameter is 500 μm. It will be appreciated that corresponding models will apply to different membrane diameters, and are intended fall within the scope of the present invention.

As can be seen, the variation is a curve such that there are two solutions for each particular first resonant frequency. In the example shown, for a resonant frequency of approximately 240 kHz, membrane thicknesses of 0.2 and 1.2 μm are appropriate. Furthermore, a thicker membrane leads to a higher Q factor. Thus, a 0.2 μm thick membrane is suitable for detecting pressure waves at or around 240 kHz, and a 1.2 μm thick membrane is suitable for transmitting pressure waves at or close to 240 kHz.

FIG. 4 shows a 2D array 30 of MEMS transducers 34 according to an embodiment of the present invention.

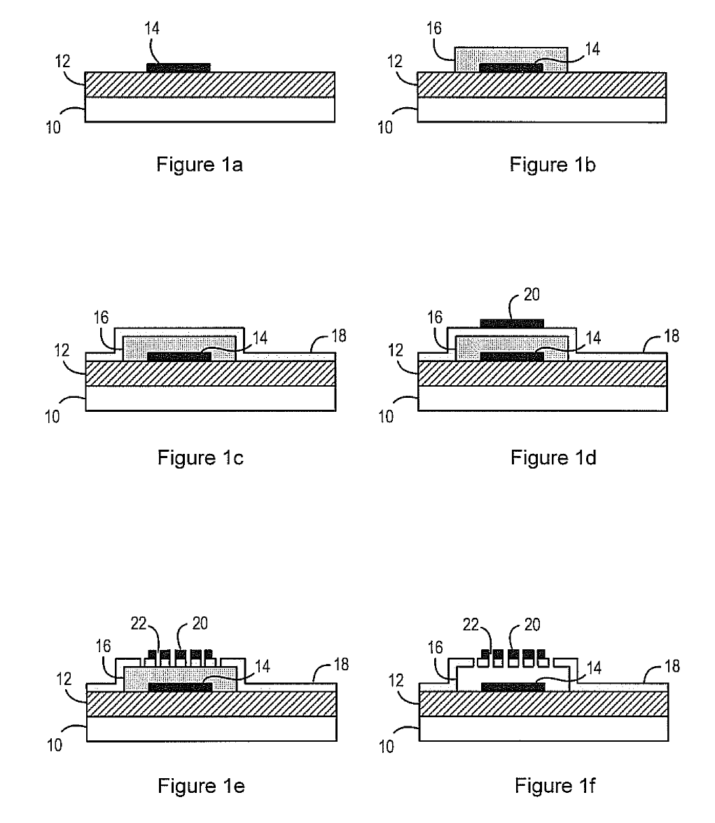

The array 30 comprises a plurality of non-identical sub-arrays 32. Each sub-array 32 comprises a plurality of MEMS transducers 34, for example as described above with respect to FIG. 1. According to the present invention, however, some of the sub-arrays 32a (unshaded elements in FIG. 4) comprise MEMS transducers specifically adapted to detect pressure waves. Others of the sub-arrays 32b (shaded elements in FIG. 4), interleaved with the “detecting” sub-arrays 32a, comprise MEMS transducers specifically adapted to transmit pressure waves.

In this application, “pressure waves” are any waves generated by oscillation of the membrane of the MEMS transducers, regardless of the frequency of those oscillations. Therefore, the term includes ultrasonic waves, as well as lower frequency, acoustic waves.

Thus, the individual MEMS transducers 34 in the plurality of sub-arrays 32a adapted to detect pressure waves may have a relatively low Q factor; the individual MEMS transducers 34 in the plurality of sub-arrays 32b adapted to transmit pressure waves may have a relatively high Q factor.

Of course, it will be apparent to those skilled in the art that the embodiment illustrated in FIG. 4 is just one possible arrangement, and that alternative arrangements of transducers are possible within the scope of the invention. In particular, sub-arrays 32 may take any shape. However, hexagonal sub-arrays 32 are advantageous because they minimize the amount of wasted space on a given substrate. Further, each sub-array 32 may not comprise exclusively transmitting or detecting transducers; rather, each sub-array 32 may comprise both transmitting and detecting transducers. In an alternative embodiment, the individual transducers 34 may not be arranged in sub-arrays as described, but in a single array.

In a still further embodiment, rather than a first plurality of substantially identical transducers for transmitting pressure waves, and a second plurality of substantially identical transducers for detecting pressure waves, a plurality of transducers may be provided having a range of transmitting or detecting properties. That is, a plurality of transducers may be provided for transmitting pressure waves, each transducer having different dimensions, Q factor, etc, such that each transducer primarily transmits at a particular, different, resonant frequency. Similarly, a plurality of transducers may be provided for detecting pressure waves, each transducer having different dimensions, Q factor, etc, such that each transducer primarily detects a particular, different, resonant frequency.

A MEMS device comprising transmitting and detecting transducers having a range of resonant frequencies is far more sensitive to different frequencies, and is capable of transmitting over a broader range of frequencies.

As previously mentioned, various dimensions, parameters, etc, may be modified in order to adapt the transducer for either transmitting or detecting pressure waves, or for adjusting the resonant frequency of the transducer. In the description of various embodiments hereinafter, references to two transducers respectively adapted to transmit and to detect pressure waves will be taken to further include two transducers adapted to transmit or to detect pressure waves at different respective frequencies.

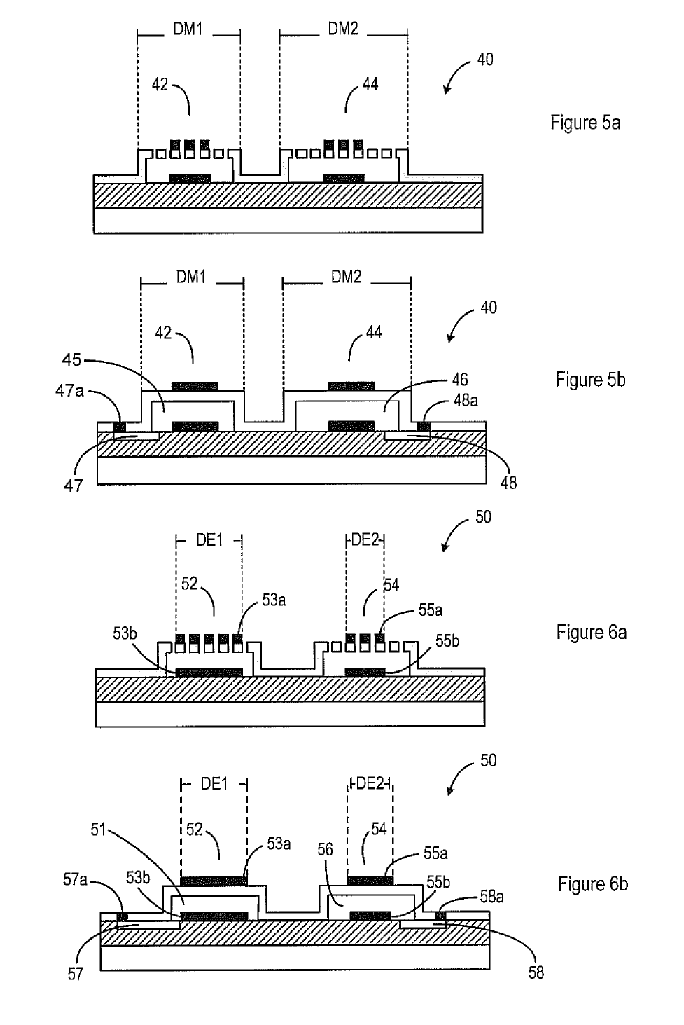

FIG. 5a illustrates a MEMS device 40 according to one embodiment of the present invention.

The MEMS device 40 comprises a first transducer 42 optimized for transmitting pressure waves, having a diameter DM1, and a second transducer 44 optimized for detecting pressure waves, having a diameter DM2. It can be seen that the diameter DM2 of the membrane of the second transducer 44 is greater than the diameter DM1 of the first transducer 42, meaning that it is more sensitive to incoming pressure waves, and therefore more suited to detecting pressure waves. The smaller diameter DM1 of the membrane of the first transducer 42 means that it can generate pressure waves having greater amplitudes, i.e. it can generate a greater variation in pressure, and is therefore more suited to transmitting pressure waves.

The embodiment shown in FIG. 5b is similar, and thus like numerals are used to indicate like components, but both transducers are sealed. The first transducer 42 comprises a first cavity 45, and the second transducer 44 a second cavity 46. The cavity 45 is formed by removal of sacrificial material via a release channel 47, while the second cavity 46 is formed by removal of sacrificial material via a release channel 48. The cavities 45, 46 are sealed after removal of the sacrificial material by plugging release holes 47a and 48a, respectively.

FIG. 6a illustrates a MEMS device 50 according to a further embodiment of the present invention and FIG. 6b illustrates a sealed embodiment.

In each case the MEMS device 50 comprises a first transducer 52 optimized for transmitting pressure waves, and a second transducer 54 optimized for detecting pressure waves. The diameter DE1 of the electrodes 53a, 53b of the first transducer 52 are greater than the diameter DE2 of the electrodes 55a, 55b of the second transducer 54. The force between the two electrodes 53a, 53b is proportional to their area, so a greater area means that a greater force can be generated by the transducer 52, making it more suitable for transmitting pressure waves because a higher amplitude can be attained. The smaller diameter of the electrodes 55a, 55b of the second transducer 54 makes the membrane more flexible, and therefore more sensitive to incoming pressure waves.

In an alternative embodiment, the mass of the electrodes may be adjusted instead of altering their diameter. A transducer with an electrode having a relatively high mass is more suitable for transmitting pressure waves, as it can generate waves with relatively higher amplitude. Likewise, a transducer with an electrode having a relatively low mass is more suitable for detecting pressure waves as the membrane is more easily deflected by the incoming wave. This may be achieved by utilizing a heavier conductor as the material for the electrode, for example, or by making the electrodes thicker.

In the embodiment shown in FIG. 6b the first transducer 52 comprises a first cavity 51, and the second transducer 54 a second cavity 56. The cavity 51 is formed by removal of sacrificial material via a release channel 57, while the second cavity 56 is formed by removal of sacrificial material via a release channel 58. The cavities 51, 56 are sealed after removal of the sacrificial material by plugging release holes 57a and 58a, respectively.

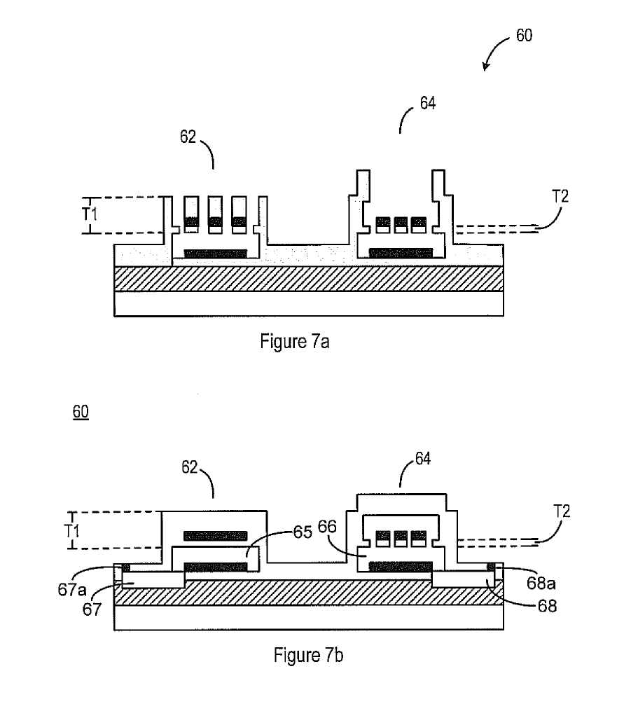

FIG. 7a illustrates a MEMS device 60 according to a yet further embodiment of the present invention.

The MEMS device 60 comprises a first transducer 62 optimized for transmitting pressure waves, having a first membrane thickness T1, and a second transducer 64 optimized for detecting pressure waves, having a second thickness T2. The membrane thickness T2 of the second transducer 64 is less than the membrane thickness T1 of the first transducer 62, meaning that the second transducer 64 is more sensitive to incoming pressure waves, and therefore more suited to detecting pressure waves. The greater thickness of the membrane of the first transducer 62 means that it can generate pressure waves having greater amplitudes, i.e. it can generate a greater variation in pressure, and is therefore more suited to transmitting pressure waves.

FIG. 7b illustrates a similar embodiment having sealed cavities. The first transducer 62 comprises a first cavity 65, and the second transducer 64 a second cavity 66. The cavity 65 is formed by removal of sacrificial material via a release channel 67, while the second cavity 66 is formed by removal of sacrificial material via a release channel 68. The cavities 65, 66 are sealed after removal of the sacrificial material by plugging release holes 67a and 68a, respectively.

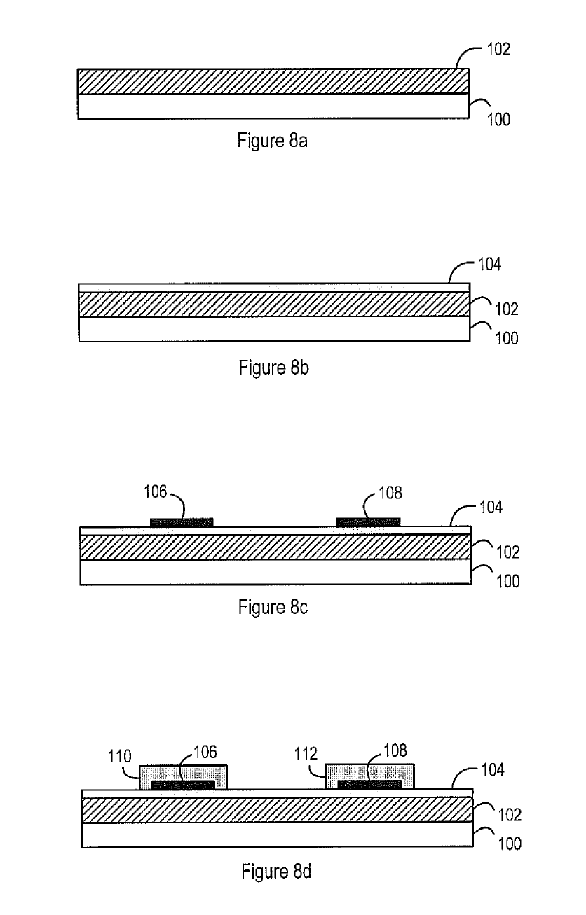

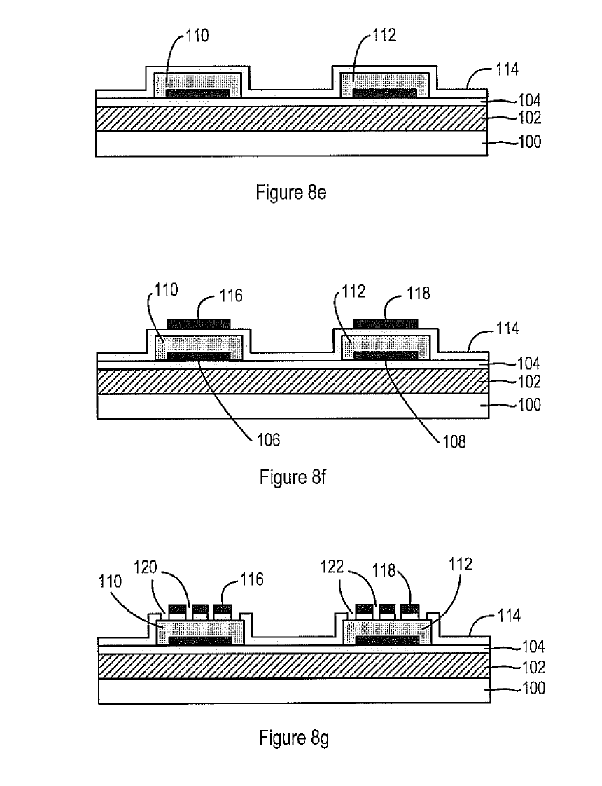

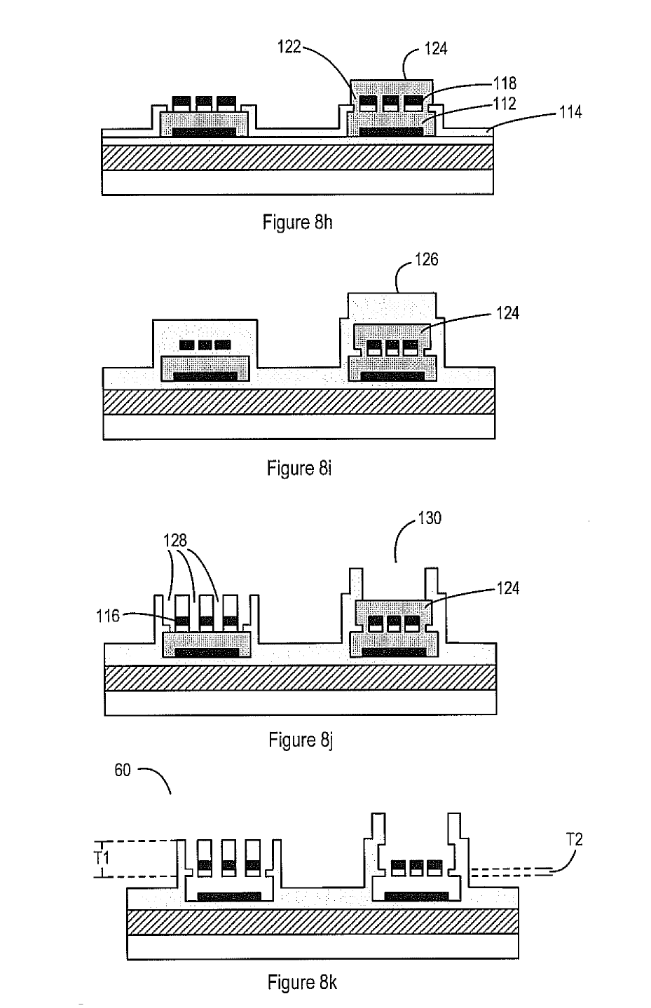

FIGS. 8a to 8k illustrate one method of manufacturing MEMS devices according to the present invention, and in particular the embodiment described with respect to FIG. 7a. However, the figures will also be used to describe a possible manufacturing process of other embodiments of the present invention.

It will be further appreciated by those skilled in the art that some of the steps of the illustrated method need not be performed in the order stated herein. However, as will also be apparent, some steps must be performed before or after others as may be, in order that the desired structure is generated.

FIG. 8a shows a starting point of the manufacturing process. A substrate 100 is provided, with an insulating layer 102 on top of the substrate. In this example, for compatibility with CMOS processing techniques the substrate 100 is a silicon wafer, but it will be appreciated that other substrate materials and electronic fabrication techniques could be used instead. The insulating layer 102 may be formed by thermal oxidation of the silicon wafer, forming an oxide layer, or by deposition of an insulating material using any one of numerous known techniques, such as plasma enhanced chemical vapour deposition (PECVD).

A base layer 104 of silicon nitride is then deposited on top of the insulating layer 102 (FIG. 8b). The base layer 104 may be deposited using PECVD. However, it will be appreciated that other dielectric layers and/or processes may be used. For example, the layer might not be pure silica; borophosphosilicate glass (BPSG) may also be used.

Next, referring to FIG. 8c, electrodes 106, 108 are deposited at the sites of a transmitting transducer and a detecting transducer, respectively. The electrodes 106, 108 may be formed by sputtering or depositing a conducting material, for example aluminium, on the surface of the base layer 104. In the present example, the electrodes 106, 108 are the same size and shape. However, when forming transducers 52, 54 as described with reference to FIG. 6, the size and/or shape of the electrodes 106, 108 may be varied at this stage. For example, the electrode 106 for the transmitting transducer may have a greater diameter, or a greater mass, than the electrode 108 for the detecting transducer.

Depositing the electrodes 106, 108 by sputtering is preferable to other methods such as thermal evaporation due to the low substrate temperatures used. This ensures compatibility with CMOS fabrication processes. In addition, where materials other than aluminium are deposited, this method benefits from the ability to accurately control the composition of the thin film that is deposited. Sputtering deposits material equally over all surfaces so the deposited thin film has to be patterned by resist application and dry etching with a Cl₂/BCl₃ gas mix to define the shape of the electrodes 106, 108 as well as to define the interconnect points (not shown in the Figures) that allow interconnection to the circuit regions (i.e. either the underlying CMOS circuit or the off-chip circuits, neither illustrated).

Next, referring to FIG. 8d, sacrificial layers 110, 112 are deposited over the electrodes 106, 108, respectively. To ensure compatibility with CMOS fabrication techniques, for example, the sacrificial layers 110, 112 can be made of a number of materials which can be removed using either a dry release or a wet release process. Using a dry release process is advantageous in that no additional process steps or drying are required after the sacrificial layer is released. Polyimide is preferable as the sacrificial layer as it can be spun onto the substrate easily and removed with an oxygen plasma clean. The polyimide coating is spun on the wafer to form a conformal coating, using parameters and techniques that will be familiar to those skilled in the art. A primer may be used for the polyimide layer. The polyimide layer is then patterned with photoresist and etched in an anisotropic oxygen plasma, thus leaving the sacrificial layers 110, 112 as shown in FIG. 8d. It will appreciated by a person skilled in the art that alternative methods of depositing the sacrificial layers 110, 112 may be used, for example applying and etching a photosensitive polyimide.

The sacrificial layers 110, 112 define the dimensions and shape of the cavities or spaces underneath the membranes that will be left when the sacrificial layers 110, 112 are removed as discussed below.

The sacrificial layers 110, 112 are provided for a number of reasons. These include supporting and protecting the membrane of the MEMS device during the manufacturing process. The sacrificial layers 110, 112 are also provided for defining the diameter of the membranes, such that the size of the membranes can be altered by altering the diameter of the sacrificial layers 110, 112. In the present example, the sacrificial layers 110, 112 are substantially identical in shape and size. However, when manufacturing transducers 42, 44 as described with respect to FIG. 5, the sacrificial layers 110, 112 may have different diameters. In particular, the sacrificial layer 110 for the transmitting transducer may have a smaller diameter that the sacrificial layer 112 for the detecting transducer.

Next, referring to FIG. 8e, a membrane layer 114 is deposited over the base layer 104 and the sacrificial layers 110, 112. The membrane layer 114 may be formed from silicon nitride deposited by PECVD, as before, although alternatively polysilicon may be used. In addition, titanium adhesive layers may be used between the aluminium and the silicon nitride.

Although not shown in FIGS. 8d and 8e, the upper surface of the sacrificial layers 110, 112 may be formed with one or more dimples (in the form of small cavities) in their outer area (i.e. near the periphery of the sacrificial layers 110, 112). As a result, the depositing of the membrane layer 114 causes one or more dimples (in the form of protrusions) to be formed in the outer area or periphery of the membrane. These dimples in the outer area of the membrane 114 reduce the contact area of the membrane with the underlying substrate in the event of overpressure or membrane pull-in, whereby the surface of the membrane comes into contact with another surface of the MEMS device. The dimples reduce the stiction forces such that they are below the restoring forces (i.e. the membrane tension), thereby allowing the membrane to release itself.

Next, referring to FIG. 8f, second electrodes 116, 118 are deposited substantially over the sacrificial layers 110, 112, respectively. In general, for simplicity of the manufacturing process, the second electrodes 116, 118 have substantially the same size and shape as their respective counterpart electrodes 106, 108; however, this is not a strict requirement. For example, when manufacturing transducers 52, 54 such as described with respect to FIG. 6, the electrode 116 for the transmitting transducer 52 may have a greater mass and/or diameter and/or thickness than the electrode 118 for the detecting transducer 54.

The second electrodes 116, 118 are deposited in substantially the same way as the first electrodes 106, 108.

Next, referring to FIG. 8g, release holes 120 are etched through the electrode 116 and the membrane layer 114 to allow access to the sacrificial layer 110, and release holes 122 are etched through the electrode 118 and the membrane layer 114 to allow access to the sacrificial layer 112. In the illustrated embodiment, the release holes 120, 122 are formed through both the membrane layer 114 and the electrodes 116, 118; however, where the electrode diameter is less than the diameter of the membrane, for example, the release holes may be positioned substantially around the periphery of the membrane, such that they do not pass through the electrodes themselves. It will be appreciated that the formation of the release holes 120, 122 through the respective electrodes 116, 118 and membrane layer 114 may be formed in one process step or several process steps depending on the materials involved, and the etching process or processes used.

It is to be noted that, when manufacturing a MEMS device 60 as described with respect to FIG. 7, release holes 120 in the transducer for transmitting pressure waves are not necessary at this stage.

At this stage, the method for manufacture of MEMS devices 40, 50 is substantially complete (i.e. membranes with differing diameters, or differing electrode diameter or size). The sacrificial layers 110, 112 are preferably removed using a dry etch process, such as an oxygen plasma system, so that the membrane is free to move in both transducers.

FIGS. 8h to 8k describe the further steps of a method for manufacturing a MEMS device 60 as described with respect to FIG. 7 (i.e. a device having transducers with differing membrane thickness).

With reference to FIG. 8h, a further sacrificial layer 124 is deposited over the electrode 118, connecting with the sacrificial layer 112 through the release holes 122. The further sacrificial layer 124 may again be formed from silicon nitride, or one of the alternative materials mentioned previously. Again, any one of the techniques previously mentioned may be used to deposit the sacrificial layer 124.

Next, referring to FIG. 8i, a further membrane layer 126 is deposited over the first membrane layer 114, the electrode 116, and the further sacrificial layer 124. In a preferred embodiment, the second membrane layer 126 is formed from the same material as the first membrane layer 114, such that the two layers 114, 126 substantially bond together to form a single layer of material. The second membrane layer 126 may be formed from any of the alternatives for the first membrane layer 114.

In FIG. 8j, release holes 128 are etched through the thickened membrane of the transmitting transducer (i.e. first and second membrane layers 114, 126). As before, the release holes 128 may pass through the electrode 116, or around the periphery of the electrode 116.

Further, the second membrane layer 126 is removed from above the sacrificial layer 124 in the detecting transducer, to create an opening 130 in the membrane layer 126.

Finally, as shown in FIG. 8k, the completed device 60 is created by removing the sacrificial layers 110, 112, 124. The sacrificial layers 110, 112, 124 are preferably removed using a dry etch process, such as an oxygen plasma system, so that the membrane is free to move in both transducers.

In the illustrated embodiment, the first and second membrane layers 114, 126 substantially encase the electrode 116 of the transmitting transducer. The formation of a sandwich structure has the advantage of reducing unwanted deformation in the membrane. In other words, if the electrode is placed between two layers of nitride, or vice versa, then the stress is more equalised, and results in the membrane moving with less unwanted deformation. However, it will be apparent to one skilled in the art that the deposition of the electrode 116 may take place at a later stage, such that the electrode 116 is positioned on top of the thickened membrane.

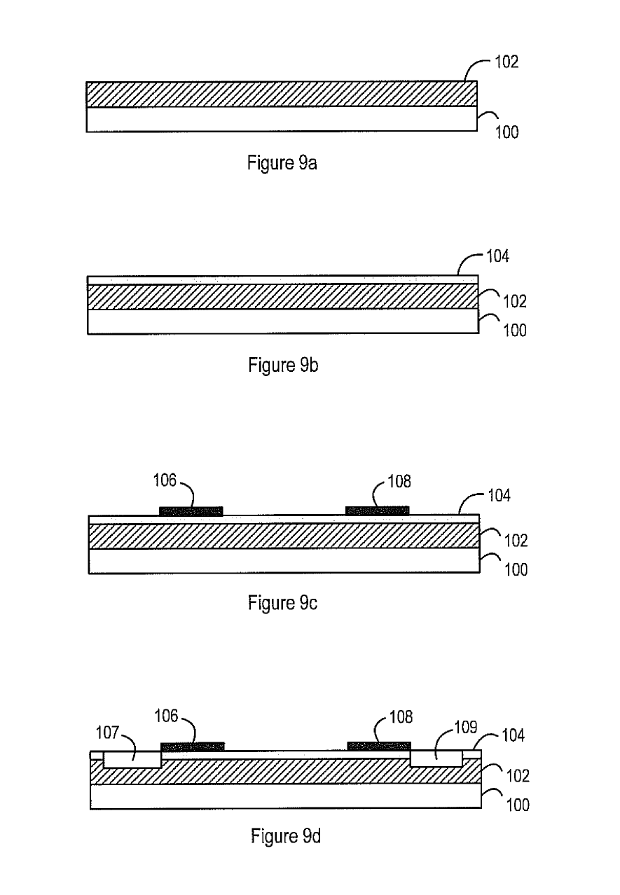

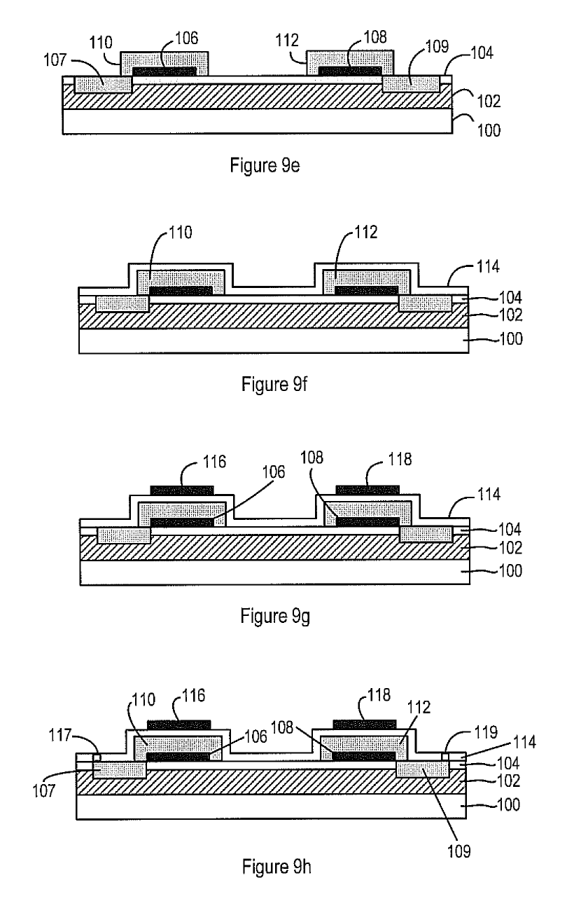

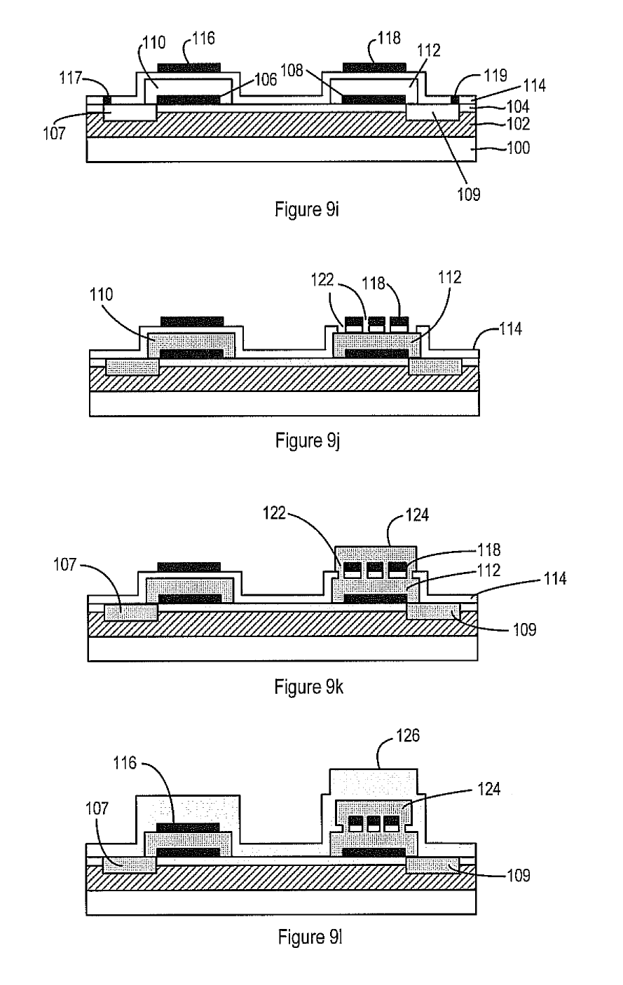

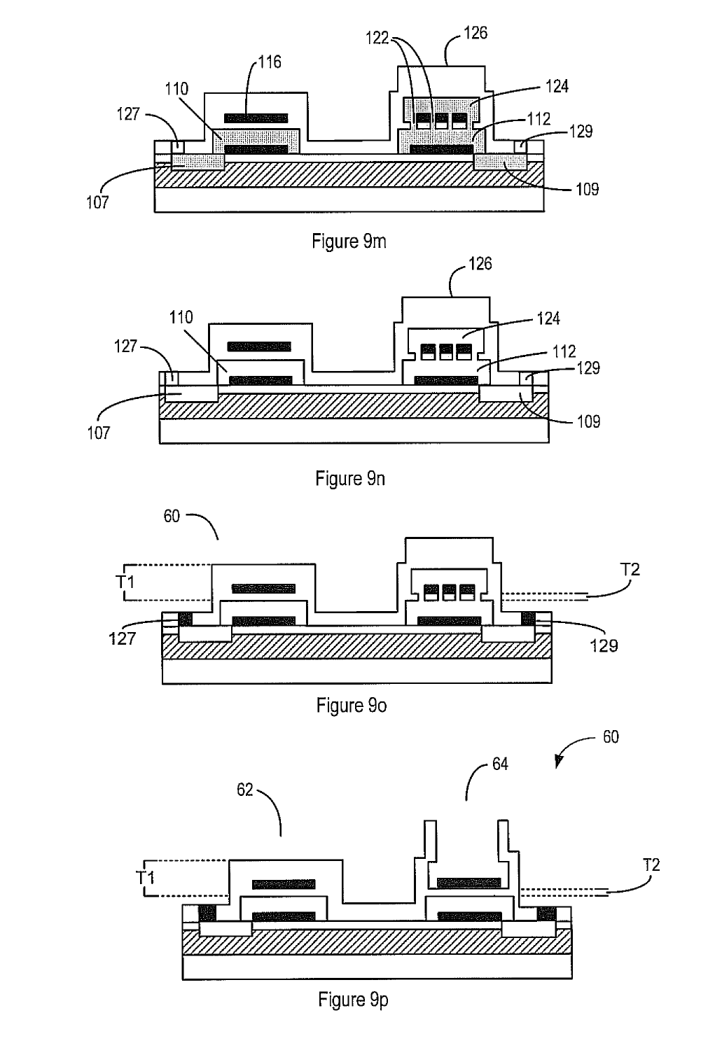

FIGS. 9a-9p illustrate a process for forming MEMS transducers according to the present invention having sealed cavities. The method may use several of the same steps and provide the same structures as describe above in relation to FIGS. 8a-8k and therefore similar reference numerals will be used.

FIG. 9a shows a starting point of the manufacturing process. A substrate 100 is provided, with an insulating layer 102 on top of the substrate. In this example, for compatibility with CMOS processing techniques the substrate 100 is a silicon wafer, but it will be appreciated that other substrate materials and electronic fabrication techniques could be used instead. The insulating layer 102 may be formed by thermal oxidation of the silicon wafer, forming an oxide layer, or by deposition of an insulating material using any one of numerous known techniques, such as plasma enhanced chemical vapour deposition (PECVD).

A base layer 104 of silicon nitride is then deposited on top of the insulating layer 102 (FIG. 9b). The base layer 104 may be deposited using PECVD. However, it will be appreciated that other dielectric layers and/or processes may be used. For example, the layer might not be pure silica; borophosphosilicate glass (BPSG) may also be used.

Next, referring to FIG. 9c, electrodes 106, 108 are deposited at the sites of a transmitting transducer and a detecting transducer, respectively. The electrodes 106, 108 may be formed by sputtering or depositing a conducting material, for example aluminium, on the surface of the base layer 104. In the present example, the electrodes 106, 108 are the same size and shape. However, when forming transducers 52, 54 as described with reference to FIG. 6b, the size and/or shape of the electrodes 106, 108 may be varied at this stage. For example, the electrode 106 for the transmitting transducer may have a greater diameter, or a greater mass, than the electrode 108 for the detecting transducer.

Depositing the electrodes 106, 108 by sputtering is preferable to other methods such as thermal evaporation due to the low substrate temperatures used. This ensures compatibility with CMOS fabrication processes. In addition, where materials other than aluminium are deposited, this method benefits from the ability to accurately control the composition of the thin film that is deposited. Sputtering deposits material equally over all surfaces so the deposited thin film has to be patterned by resist application and dry etching with a Cl₂/BCl₃ gas mix to define the shape of the electrodes 106, 108 as well as to define the interconnect points (not shown in the Figures) that allow interconnection to the circuit regions (i.e. either the underlying CMOS circuit or the off-chip circuits, neither illustrated).

Next, referring to FIG. 9d, release channels 107, 109 are formed in the base layer 104 and insulating layer 102. The release channels 107, 109 are provided in order to enable an etching path to be formed with the sacrificial material that is to be deposited in subsequent steps, as will be explained below. Although the release channels 107, 109 are shown as penetrating into the base layer 104 and insulating layer 102, it is noted that the release channels could also be formed such that they penetrate into the base layer 104 only. Furthermore, in an embodiment where a base layer 104 is not provided, the release channels 107, 109 will penetrate the insulating layer 102 only. Furthermore, although not shown, the release channels may form part of the substrate 100.

There are numerous possibilities for realising the release channels 107, 109. For example, the release channels 107, 109 can be formed as one continuous channel that is fabricated around the periphery of the MEMS transducer. In other words, the release channels 107, 109 shown in FIG. 9d form part of a continuous trough or ring around the MEMS transducer. According to another embodiment, each release channel 107, 109 can be formed as a discrete channel that creates a tunnel like structure for allowing the etching material to reach the sacrificial material. In the latter embodiment, a plurality of separate release channels 107, 109 may be formed around the periphery of the MEMS transducer.

It is noted that steps 9c and 9d may be reversed, if desired, so that the release channels 107, 109 are formed prior to depositing the electrodes 106, 108. In such a method, sacrificial material may be deposited within the formed release channels 107, 109 prior to depositing the electrodes 106, 108.

Next, referring to FIG. 9e, sacrificial layers 110, 112 are deposited over the electrodes 106, 108, respectively. The sacrificial material used for depositing the sacrificial layers 110, 112 may also be deposited within the release channels 107, 109, assuming that the release channels 107, 109 have not been previously filled, as described in the preceding paragraph. To ensure compatibility with CMOS fabrication techniques, the sacrificial layers 110, 112 can be made of a number of materials which can be removed using either a dry release or a wet release process. Using a dry release process is advantageous in that no additional process steps or drying are required after the sacrificial layer is released. Polyimide is preferable as the sacrificial layer as it can be spun onto the substrate easily and removed with an oxygen plasma clean. The polyimide coating is spun on the wafer to form a conformal coating, using parameters and techniques that will be familiar to those skilled in the art. A primer may be used for the polyimide layer. The polyimide layer is then patterned with photoresist and etched in an anisotropic oxygen plasma, thus leaving the sacrificial layers 110, 112, plus sacrificial material in the release channels 107, 109, as shown in FIG. 9e. It will appreciated by a person skilled in the art that alternative methods may be used for depositing the sacrificial layers 110, 112 and sacrificial material in the release channels 107, 109, for example applying and etching a photosensitive polyimide.

As can be seen from FIG. 9e, the sacrificial layers 110, 112 are formed such that a portion of each sacrificial layer 110, 112, overlaps a portion of the respective release channels 107, 109.

The sacrificial layers 110, 112 define the dimensions and shape of the cavities underneath the membranes that will be left when the sacrificial layers 110, 112 are removed as discussed below.

The sacrificial layers 110, 112 are provided for a number of reasons. These include supporting and protecting the membrane of the MEMS device during the manufacturing process. The sacrificial layers 110, 112 are also provided for defining the diameter of the membranes, such that the size of the membranes can be altered by altering the diameter of the sacrificial layers 110, 112. In the present example, the sacrificial layers 110, 112 are substantially identical in shape and size, However, when manufacturing transducers 42, 44 as described with respect to FIG. 5b, the sacrificial layers 110, 112 may have different diameters. In particular, the sacrificial layer 110 for the transmitting transducer may have a narrower diameter that the sacrificial layer 112 for the detecting transducer.

Next, referring to FIG. 9f, a membrane layer 114 is deposited over the sacrificial layers 110, 112, over at least a portion of the base layer 104, and over a portion of the release channels 107, 119. The membrane layer 114 may be formed from silicon nitride deposited by PECVD, as before, although alternatively polysilicon may be used. In addition, titanium adhesive layers may be used between the aluminium and the silicon nitride.

Although not shown in FIGS. 9e and 9f, the upper surface of the sacrificial layers 110, 112 may be formed with one or more dimples (in the form of small cavities) in their outer area (i.e. near the periphery of the sacrificial layers 110, 112). As a result, the depositing of the membrane layer 114 causes one or more dimples (in the form of protrusions) to be formed in the outer area or periphery of the membrane. These dimples in the outer area of the membrane 114 reduce the contact area of the membrane with the underlying substrate in the event of overpressure or membrane pull-in, whereby the surface of the membrane comes into contact with another surface of the MEMS device. The dimples reduce the stiction forces such that they are below the restoring forces (i.e. the membrane tension), thereby allowing the membrane to release itself.

Next, referring to FIG. 9g, second electrodes 116, 118 are deposited substantially over the sacrificial layers 110, 112, respectively. In general, for simplicity of the manufacturing process, the second electrodes 116, 118 have substantially the same size and shape as their respective counterpart electrodes 106, 108; however, this is not a strict requirement. For example, when manufacturing transducers 52, 54 such as described with respect to FIG. 6b, the electrode 116 for the transmitting transducer 52 may have a greater mass and/or diameter and/or thickness than the electrode 118 for the detecting transducer 54.

The second electrodes 116, 118 are deposited in substantially the same way as the first electrodes 106, 108.

At this stage, the method for manufacture of MEMS devices 40, 50 is substantially complete (i.e. membranes with differing diameters, or differing electrode diameter or size), apart from the removal of the sacrificial layers 110, 112, are will be described below.

Next, referring to FIG. 9h, a release hole 117 is etched through the membrane layer 114 to allow access to the sacrificial material in the release channel 107, which in turn is connected to the sacrificial layer 110. In a similar manner, a release hole 119 is etched in the membrane layer 114 to allow access to the sacrificial material in the release channel 109, which in turn is connected to the sacrificial layer 112. As can be seen, the first and second release holes 117, 119 are formed through the membrane layer 114 in areas which correspond to second portions of the respective release channels 107, 109, the second portions of the respective release channels 107, 109 being outside the respective areas defined by the first and second sacrificial layers 110, 112.

The sacrificial material, both in the release channels 107, 109 and the sacrificial layers 110, 112, is preferably removed using a dry etch process, such as an oxygen plasma system, so that the membrane is free to move in both transducers.

Referring to FIG. 9i, after removal of the sacrificial material from the release channels 107, 109 and sacrificial layers 110, 112, the release holes 117, 119 are sealed or plugged with a suitable sealant, thus preventing moisture or other environmental parameters from penetrating the MEMS transducer.

FIGS. 9j to 90 describe alternative steps to those shown in FIGS. 9h to 9i, for manufacturing a MEMS device 60 as described with respect to FIG. 7b (i.e. a device having transducers with differing membrane thickness).

Thus, according to this embodiment, once the MEMS device has been fabricated up to step 9g, the following steps are followed in order to fabricate a MEMS device 60 as described with respect to FIG. 7b. Referring to FIG. 9j, release holes 122 are etched through the electrode 118 and the membrane layer 114 to allow access to the sacrificial layer 112. In the illustrated embodiment, the release holes 122 are formed through both the membrane layer 114 and the electrode 118; however, where the electrode diameter is less than the diameter of the membrane, for example, the release holes may be positioned substantially around the periphery of the membrane, such that they do not pass through the electrode itself. It will be appreciated that the formation of the release holes 122 through the electrode 118 and membrane layer 114 may be formed in one process step or several process steps depending on the materials involved, and the etching process or processes used.

With reference to FIG. 9k, a further sacrificial layer 124 is deposited over the electrode 118, connecting with the sacrificial layer 112 through the release holes 122. The further sacrificial layer 124 may again be formed from silicon nitride, or one of the alternative materials mentioned previously. Again, any one of the techniques previously mentioned may be used to deposit the sacrificial layer 124.

Next, referring to FIG. 9l, a further membrane layer 126 is deposited over the first membrane layer 114, the electrode 116, and the further sacrificial layer 124. In a preferred embodiment, the second membrane layer 126 is formed from the same material as the first membrane layer 114, such that the two layers 114, 126 substantially bond together to form a single layer of material. The second membrane layer 126 may be formed from any of the alternatives for the first membrane layer 114.

In FIG. 9m, a release hole 127 is etched through the membrane layer 114 to allow access to the sacrificial material in the release channel 107, which in turn is connected to the sacrificial layer 110. In a similar manner, a release hole 129 is etched in the membrane layer 114 to allow access to the sacrificial material in the release channel 109, which in turn is connected to the sacrificial layer 112, and to the sacrificial layer 124 via the release holes 122.

Next, as shown in FIG. 9n, the completed device 60 is created by removing the sacrificial material from the release channels 107, 109 and the sacrificial layers 110, 112, 124. The sacrificial material from the release channels 107, 109 and the sacrificial layers 110, 112, 124 is preferably removed using a dry etch process, such as an oxygen plasma system, so that the membrane is free to move in both transducers.

Finally, as shown in FIG. 9o, the MEMS device is sealed and protected from environmental parameters by sealing the holes 127, 129.

The resulting MEMS device 60 comprises a first transducer having a membrane with a first thickness T1, and a second transducer having an effective membrane with a second thickness T2. The transducer having the membrane with the first thickness T1 is particularly suited for use as a transmitter, while the transducer having the membrane with the second thickness T2, where T2<T1, is particularly suited for use as a receiver.

In FIGS. 9j to 9o the fabrication of the second transducer is shown as having release holes 122 for enabling the sacrificial material 124 to be etched by first etching away the sacrificial material from the release channel 109 and the sacrificial layer 112. However, according to a further embodiment, the step of etching release holes in FIG. 9j can be omitted, and instead the sacrificial layer 124 removed as follows. The steps shown in FIGS. 9k-9o would be followed as above. However, the absence of release holes 122 would result in the sacrificial layer 124 being inaccessible using the release channel 109 and the sacrificial layer 112. As such, the sacrificial layer 124 is removed by first removing a portion of the membrane 126, and then etching away the sacrificial layer 124 from above. This would result in a device as shown in FIG. 9p. The resulting device is still sealed, in so far as the cavity created by the removal of the sacrificial layer 112 is sealed from the environment.

Although the method of fabricating a sealed transducer has been described in relation to a device having first and second transducers on the same substrate, it is noted that the method is also applicable to the fabrication of a single transducer.

In the illustrated embodiment, the first and second membrane layers 114, 126 substantially encase the electrode 116 of the transmitting transducer. The formation of a sandwich structure has the advantage of reducing unwanted deformation in the membrane. In other words, if the electrode is placed between two layers of nitride, or vice versa, then the stress is more equalised, and results in the membrane moving with less unwanted deformation. However, it will be apparent to one skilled in the art that the deposition of the electrode 116 may take place at a later stage, such that the electrode 116 is positioned on top of the thickened membrane.

A person skilled in the art will further appreciate that not described in the methods above are steps for depositing connection pads for the electrodes. However, it will be apparent that these may be deposited and connected to the electrodes at various stages throughout the method. Further, future technology may allow the direct integration of electronics within the transducers themselves; such developments may of course still be considered as falling within the scope of the present invention, as defined by the claims appended hereto.

It can be seen, therefore, that the present invention provides methods for manufacturing first and second transducers 62, 64 having differing membrane thicknesses on the same substrate and in the same process.

It will be appreciated that various combinations of the embodiments described above may be combined in a particular transducer or transducer array. That is, although the illustrated embodiments describe transducers with only one differing parameter/dimension on a single substrate, it will be appreciated that transducers on a single substrate may have any combination of different membrane thickness, different membrane diameter, and different electrode diameter, thickness or mass. Any or all of the above parameters may be varied in order to obtain a particular resonant frequency or frequency response characteristic for a transducer.

Further, although the description has been primarily directed towards a substrate with a first transducer adapted for transmitting pressure waves and a second transducer adapted for detecting pressure waves, it will be appreciated that the present invention also provides a substrate with two or more transducers adapted to transmit or to receive pressure waves, wherein the two or more transducers have different respective resonant frequencies.

In addition, it is noted that, although not shown in any of the embodiments, the transducers may be provided with a back volume.

The invention may also be used in an application whereby the MEMS device is formed in a housing or structure, and whereby a fluid for enhancing the transmission of ultrasonic waves is provided in said housing, for example between the MEMS device and a surface of the housing or structure. The housing may be used in an imaging application.

The present invention may be embodied in a number of systems and devices, including, for example, medical ultrasound imagers and sonar receivers and transmitters, as well as mobile phones, PDAs, MP3 players and laptops for gesture recognition purposes.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope. A method claim reciting a plurality of steps in a certain order does not exclude a method comprising that plurality of steps in an alternative order, except where expressly stated.

1. A microelectromechanical systems (MEMS) device, comprising:
a substrate; and
a plurality of transducers positioned on the substrate, said plurality of transducers comprising:
at least a first transducer adapted to transmit pressure waves; and
at least a second transducer adapted to detect pressure waves.

2. A MEMS device as claimed in claim 1 wherein at least one of said first and second transducers comprises a cavity, said cavity being sealed from the outside of the transducer.

3. A MEMS device as claimed in claim 1 or claim 2, wherein said first transducer has a first Q factor, and wherein said second transducer has a second Q factor, said first Q factor being higher than said second Q factor.

4. A MEMS device as claimed in any preceding claim, wherein said first transducer comprises a first membrane, and wherein said second transducer comprises a second membrane.

5. A MEMS device as claimed in claim 4, wherein said first membrane has a first thickness, and wherein said second membrane has a second thickness, said first thickness being different from said second thickness.

6. A MEMS device as claimed in claim 5, wherein said first thickness is greater than said second thickness.

7. A MEMS device as claimed in any one of claims 4 to 6, wherein said first membrane has a first diameter, and wherein said second membrane has a second diameter, said first diameter being different from said second diameter.

8. A MEMS device as claimed in claim 7, wherein said first diameter is smaller than said second diameter.

9. A MEMS device as claimed in any one of claims 4 to 8, wherein said first transducer comprises a first electrode positioned on the first membrane, said first electrode having a first mass, and wherein said second transducer comprises a second electrode positioned on the second membrane, said second electrode having a second mass, said first mass being different from said second mass.

10. A MEMS device as claimed in claim 9, wherein said first mass is greater than said second mass.

11. A MEMS device as claimed in any one of claims 4 to 10, wherein said first transducer comprises a first electrode positioned on the first membrane, said first electrode having a first diameter, and wherein said second transducer comprises a second electrode positioned on the second membrane, said second electrode having a second diameter, said first diameter being different from said second diameter.

12. A MEMS device as claimed in claim 11, wherein said first diameter is greater than said second diameter.

13. A MEMS device as claimed in any one of the preceding claims, wherein the plurality of transducers further comprises a first plurality of transducers adapted to detect pressure waves.

14. A MEMS device as claimed in claim 13, wherein each transducer of said first plurality of transducers is adapted to primarily detect a pressure wave having a different respective frequency.

15. A MEMS device as claimed in any one of the preceding claims, wherein the plurality of transducers further comprises a second plurality of transducers adapted to transmit pressure waves.

16. A MEMS device as claimed in claim 14, wherein each transducer of said second plurality of transducers is adapted to primarily transmit a pressure wave having a different respective frequency.

17. A MEMS device as claimed in any one of claims 13 to 16, wherein each transducer of said first plurality of transducers, or each transducer of said second plurality of transducers, has a different respective Q factor.

18. A MEMS device as claimed in any one of claims 13 to 17, wherein each transducer of said first plurality of transducers, or each transducer of said second plurality of transducers, comprises a respective membrane.

19. A MEMS device as claimed in claim 18, wherein each respective membrane has a different respective thickness.

20. A MEMS device as claimed in claim 18 or 19, wherein each respective membrane has a different respective diameter.

21. A MEMS device as claimed in any one of claims 18 to 20, wherein each respective membrane comprises a respective electrode, each respective electrode having a different respective mass.

22. A MEMS device as claimed in any one of claims 18 to 20, wherein each respective membrane comprises a respective electrode, each respective electrode having a different respective diameter.

23. A method of manufacturing a microelectromechanical systems (MEMS) device, said MEMS device comprising a substrate, said substrate having at least a first site for a first transducer adapted to transmit pressure waves and at least a second site for a second transducer adapted to detect pressure waves, said method comprising:
forming said first transducer on said first site, and said second transducer on said second site.

24. A method as claimed in claim 23, wherein said forming step further comprises:
depositing a first portion of sacrificial material at the first site;
depositing a second portion of sacrificial material at the second site; and
depositing a first membrane layer over at least the first site and the second site.

25. A method as claimed in claim 24, further comprising:
depositing a third portion of sacrificial material at the second site; and
depositing a second membrane layer over at least the first site and the second site.

26. A method as claimed in claim 25, further comprising:
etching away said second membrane layer from the second site, such that the overall membrane is thicker at said first site than at said second site.

27. A method as claimed in claim 24, wherein said first portion of sacrificial material has a different diameter than said second portion of sacrificial material.

28. A method as claimed in claim 27, wherein the diameter of said first portion of sacrificial material is smaller than the diameter of said second portion of sacrificial material.

29. A method as claimed in claim 24, further comprising:
depositing a first electrode at the first site; and
depositing a second electrode at the second site, wherein a mass of said first electrode is different from a mass of said second electrode.

30. A method as claimed in claim 29, wherein the mass of said first electrode is greater than the mass of said second electrode.

31. A method as claimed in claim 24, further comprising:
depositing a first electrode at the first site; and
depositing a second electrode at the second site, wherein a diameter of said first electrode is different from a diameter of said second electrode.

32. A method as claimed in claim 31, wherein the diameter of said first electrode is greater than the diameter of said second electrode.

33. A method of manufacturing a microelectromechanical systems (MEMS) device, said MEMS device comprising a substrate, said substrate having at least a first site for a first transducer adapted to transmit or detect pressure waves, said method comprising:
depositing a first portion of sacrificial material on said first site,
depositing a first membrane layer over at least the first site,
forming a release channel prior to the step of depositing the first portion of sacrificial material;
etching away the first portion of sacrificial material via the release channel; and
sealing the release channel.

34. A method as claimed in claim 33, wherein the release channel is formed in a base layer that supports the first portion of sacrificial material.

35. A method as claimed in claim 33 or 34, wherein the release channel is formed in an insulating layer that supports the first portion of sacrificial material.

36. A method as claimed in any one of claims 33 to 35, wherein the release channel comprises a first portion that is positioned within an area corresponding to the first site, and a second portion which is positioned outside the area corresponding to the first site

37. A method as claimed in claim 36, wherein the step of depositing the first portion of sacrificial material comprises the step of depositing sacrificial material within the release channel.

38. A method as claimed in claim 37, wherein the step of depositing the membrane layer comprises the step of depositing the membrane layer over the second portion of the release channel.

39. A method as claimed in claim 38, further comprising the step of forming a release hole through the membrane layer in an area corresponding to the second portion of the release channel.

40. A method as claimed in any one of claims 33 to 39, wherein the first transducer on said first site is adapted to transmit pressure waves, and wherein the method further comprises the step of forming a second transducer on a second site of said substrate, said second transducer adapted to detect pressure waves.

41. A method as claimed in claim 40, wherein the second transducer on said second site is formed by:
depositing a second portion of sacrificial material on said second site,
depositing a second membrane layer over at least the second site,
forming a release channel prior to the step of depositing the second portion of sacrificial material;
etching away the second portion of sacrificial material via the release channel; and
sealing the release channel.

42. A method as claimed in claim 41, further comprising:
depositing a third portion of sacrificial material at the second site; and
depositing a second membrane layer over at least the first site and the second site.

43. A method as claimed in claim 42, further comprising:
etching away said second membrane layer from the second site, such that the overall membrane is thicker at said first site than at said second site.

44. A method as claimed in claim 41, wherein said first portion of sacrificial material has a different diameter than said second portion of sacrificial material.

45. A method as claimed in claim 44, wherein the diameter of said first portion of sacrificial material is smaller than the diameter of said second portion of sacrificial material.

46. A method as claimed in claim 41, further comprising:
depositing a first electrode at the first site; and
depositing a second electrode at the second site, wherein a mass of said first electrode is different from a mass of said second electrode.

47. A method as claimed in claim 46, wherein the mass of said first electrode is greater than the mass of said second electrode.

48. A method as claimed in claim 41, further comprising:
depositing a first electrode at the first site; and
depositing a second electrode at the second site, wherein a diameter of said first electrode is different from a diameter of said second electrode.

49. A method as claimed in claim 48, wherein the diameter of said first electrode is greater than the diameter of said second electrode.

50. A microelectromechanical systems (MEMS) device, comprising:
a substrate; and
a plurality of transducers positioned on the substrate, said plurality of transducers comprising:
at least a first transducer adapted to transmit or detect pressure waves having a first frequency; and
at least a second transducer adapted to transmit or detect pressure waves having a second frequency,
wherein said first frequency is different from said second frequency.

51. A MEMS device as claimed in claim 50 wherein at least one of said first and second transducers comprises a cavity, said cavity being sealed from the outside of the transducer.

52. A MEMS device as claimed in claim 50 or claim 51, wherein said first transducer comprises a first membrane, and wherein said second transducer comprises a second membrane.

53. A MEMS device as claimed in claim 52, wherein said first membrane has a first thickness, and wherein said second membrane has a second thickness, said first thickness being different from said second thickness.

54. A MEMS device as claimed in claim 52 or 53, wherein said first membrane has a first diameter, and wherein said second membrane has a second diameter, said first diameter being different from said second diameter.

55. A MEMS device as claimed in any one of claims 52 to 54, wherein said first transducer comprises a first electrode positioned on the first membrane, said first electrode having a first mass, and wherein said second transducer comprises a second electrode positioned on the second membrane, said second electrode having a second mass, said first mass being different from said second mass.

56. A MEMS device as claimed in any one of claims 52 to 55, wherein said first transducer comprises a first electrode positioned on the first membrane, said first electrode having a first diameter, and wherein said second transducer comprises a second electrode positioned on the second membrane, said second electrode having a second diameter, said first diameter being different from said second diameter.

57. A method of manufacturing a microelectromechanical systems (MEMS) device, said MEMS device comprising a substrate, said substrate having at least a first site for a first transducer adapted to transmit or detect pressure waves having a first frequency and at least a second site for a second transducer adapted to transmit or detect pressure waves having a second frequency, said first frequency being different from said second frequency, said method comprising:
forming said first transducer on said first site, and said second transducer on said second site.

58. A method as claimed in claim 57, wherein said forming step further comprises:
depositing a first portion of sacrificial material at the first site;
depositing a second portion of sacrificial material at the second site; and
depositing a first membrane layer over at least the first site and the second site.

59. A method as claimed in claim 58, further comprising:
depositing a third portion of sacrificial material at the second site; and
depositing a second membrane layer over at least the first site and the second site.

60. A method as claimed in claim 59, further comprising:
etching away said second membrane layer from the second site, such that the overall membrane is thicker at said first site than at said second site.

61. A method as claimed in claim 58, wherein said first portion of sacrificial material has a different diameter than said second portion of sacrificial material.

62. A method as claimed in claim 58, further comprising:
depositing a first electrode at the first site; and
depositing a second electrode at the second site, wherein a mass of said first electrode is different from a mass of said second electrode.

63. A method as claimed in claim 58, further comprising:
depositing a first electrode at the first site; and
depositing a second electrode at the second site, wherein a diameter of said first electrode is different from a diameter of said second electrode.

64. An ultrasound imager, comprising:
a MEMS device as claimed in any one of claims 1 to 22, and 50 to 56.

65. A sonar transmitter, comprising:
a MEMS device as claimed in any one of claims 1 to 22, and 50 to 56.

66. A sonar receiver, comprising:
a MEMS device as claimed in any one of claims 1 to 22, and 50 to 56.

67. A mobile phone, comprising:
a MEMS device as claimed in any one of claims 1 to 22, and 50 to 56.

68. A personal desktop assistant, comprising:
a MEMS device as claimed in any one of claims 1 to 22, and 50 to 56.

69. An MP3 player, comprising:
a MEMS device as claimed in any one of claims 1 to 22, and 50 to 56.

70. A laptop, comprising:
a MEMS device as claimed in any one of claims 1 to 22, and 50 to 56.

71. An imaging device comprising a housing, wherein a MEMS device as claimed in any one of claims 1 to 22, and 50 to 56 is provided within the housing.

72. An imaging device as claimed in claim 71, further comprising a fluid within said housing.
